(19) United States
(12) Patent Application Publication
(10) Pub. No.: US 2026/0068101 A1
(43) Pub. Date: Mar. 5, 2026

(54) CONTROLLABLE CONNECTION MECHANISM

(71) Applicant: Dell Products L.P., Round Rock, TX (US)

(72) Inventor: TIMOTHY ALLEN SHEDD, Lithia, FL (US)

(21) Appl. No.: 18/820,545

(22) Filed: Aug. 30, 2024

(51) Int. Cl. H05K 7/20; H05K 7/14

(52) U.S. Cl. CPC H05K 7/20645; H05K 7/1495; H05K 7/20272

(57) ABSTRACT

Methods, systems, and devices for managing a data processing system that provides computer implemented services are disclosed. To provide the computer implemented services, a system may include a chassis adapted to house hardware components of the data processing system. To dissipate heat generated by the hardware components, the system may further include a quick connection adapted to place the chassis in fluid communication with a manifold through which cooling fluid flows, and a disconnection mechanism adapted to disconnect the quick connection while the chassis is positioned at a first location in a rack, the quick connection being inaccessible while the chassis is at the first location.

### FIELD

Embodiments disclosed herein relate generally to management of data processing systems. More particularly, embodiments disclosed herein relate to systems and methods for mitigating damage to data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIGS. 2A-2F show diagrams illustrating a quick connection and a disconnection mechanism in accordance with an embodiment.

FIG. 3 shows a flow diagram illustrating a method for managing a flow of a cooling fluid in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing data processing systems that may provide, at least in part, computer implemented services. The computer implemented services may be provided to any type and/or number of other devices and/or users of the data processing systems. Furthermore, the provided computer implemented services may be of any quantity and/or type of such services.

To provide the computer implemented services, data processing systems may include hardware components. For example, operation of these hardware components may facilitate various functionalities of a data processing system, thereby causing the data processing system to provide the computer implemented services.

However, the operation of said hardware components may generate heat. To regulate this heat, a liquid cooling system may be used to circulate a cooling liquid to dissipate at least a portion of the heat generated by the hardware components.

However, by circulating the cooling liquid (and/or otherwise have liquid within the system), a likelihood of liquid damage may be increased within the system. For example, should the liquid cooling system leak at least a portion of the liquid, the hardware components may be vulnerable to liquid damage.

Consequently, such liquid damage may negatively impact the operation of the hardware components. In turn, this damage may also negatively impact the computer implemented services to be provided by the system.

To decrease the likelihood of these negative impacts, a controllable connection mechanism may be used to disconnect a quick connection that is adapted to place the chassis in fluid communication with a manifold through which cooling fluid for heat dissipation flows from. Based on its functionality, this controllable connection mechanism may also be referred to as a disconnection mechanism.

For example, this controllable connection mechanism may be used with a rack system in which one or more chassis are mounted, the manifold providing the cooling fluid to each of the chassis and thus, being in fluid communication with each of the chassis. This fluid communication may be facilitated by quick connections and based on an identification of a leak within the system, the controllable connection mechanism may allow for the quick connections to be severed, thereby mitigating damage caused by a leak by stopping circulation of additional cooling fluid from the manifold. By having less fluid circulating, there is less cooling fluid available to escape through the leak.

In an embodiment, a rack system is provided.

This rack system may include a chassis adapted to house hardware components of a data processing system that provides computer implemented services; a quick connection adapted to place the chassis in fluid communication with a manifold through which cooling fluid flows; and a disconnection mechanism adapted to disconnect the quick connection while the chassis is positioned at a first location in a rack, the quick connection being inaccessible while the chassis is at the first location.

The disconnection mechanism may include a sliding horizontal tube that connects a vertical tube of the manifold with the quick connection; and is adapted to slide into the vertical tube to facilitate repositioning of the quick connection.

The rack system may further include a seal plate that may include a first sealing surface to seal the seal plate to the vertical tube and a second sealing surface to seal the seal plate to a slidable tube that connects the quick connection to the vertical tube.

The disconnection mechanism may further include a spring adapted to apply force to a blind-mate connection plate on which the quick connection is positioned, the force preventing the quick connection from moving away from the chassis when the chassis applies force to the quick connection.

The disconnection mechanism may further include a retention mechanism adapted to effectively prevent the spring from applying the force to the blind-mate connection plate.

The disconnection mechanism may further include a guide rod that controls a movement path of the blind-mate connection plate when the retention mechanism prevents the spring from applying the force to the blind-mate connection plate.

The movement path may be aligned with a movement path of the chassis when the chassis is positioned at the first location.

The movement path may move the quick connection away from the chassis.

The cooling fluid may flow through an interior of the chassis to cool a hardware component that contributes to the computer implemented services.

The rack system may further include a leak sensor positioned in the interior of the chassis, adapted to detect leaks due to the cooling fluid, and operably connected to the disconnection mechanism to activate the disconnection mechanism when a leak is present.

In an embodiment, a disconnection mechanism for use with a data processing system is provided as discussed above.

In an embodiment, a disconnection mechanism for use with a fluid distribution system is provided as discussed above.

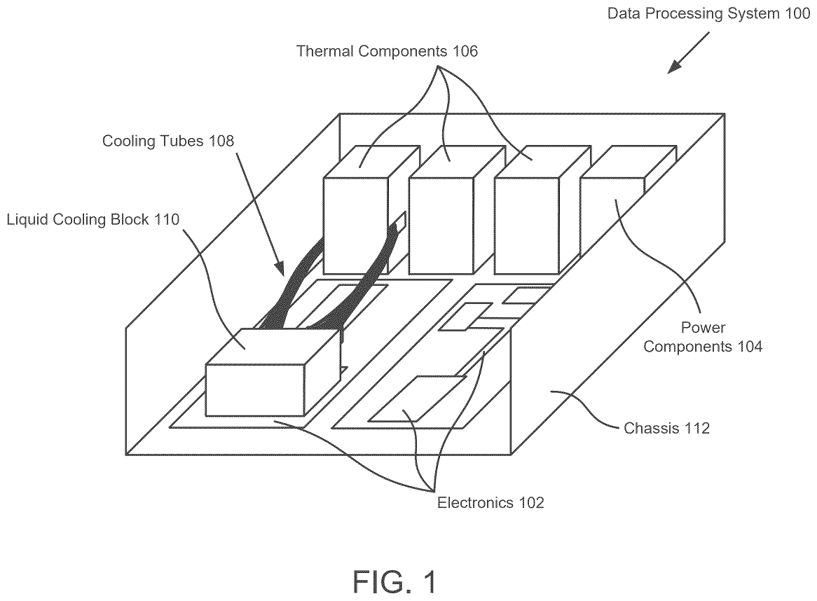

Turning to FIG. 1, a block diagram illustrating a system in accordance with an embodiment is shown. The system shown in FIG. 1 may be a distributed system that provides for management of data processing systems that may provide, at least in part, computer implemented services.

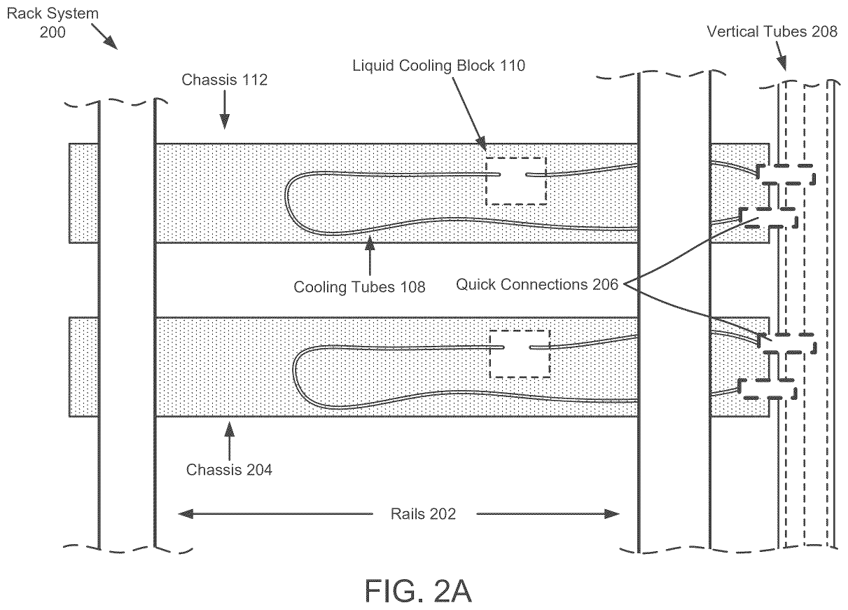

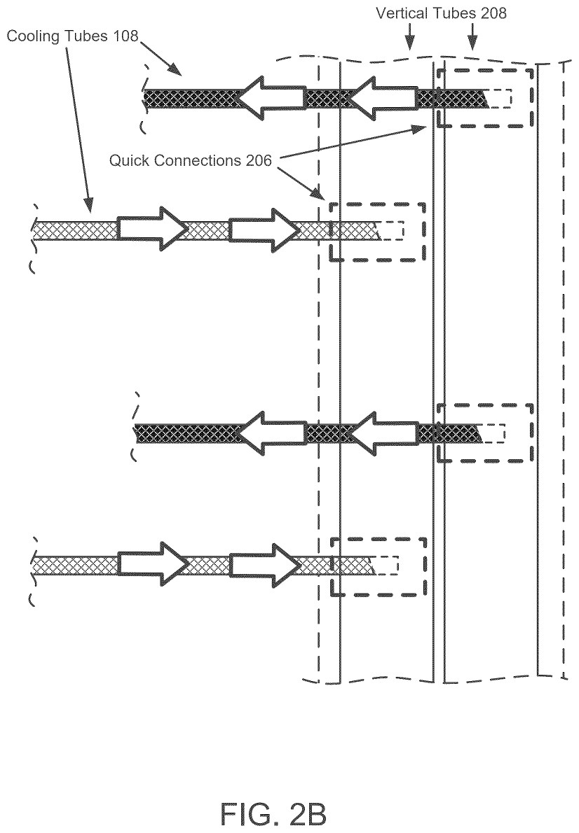

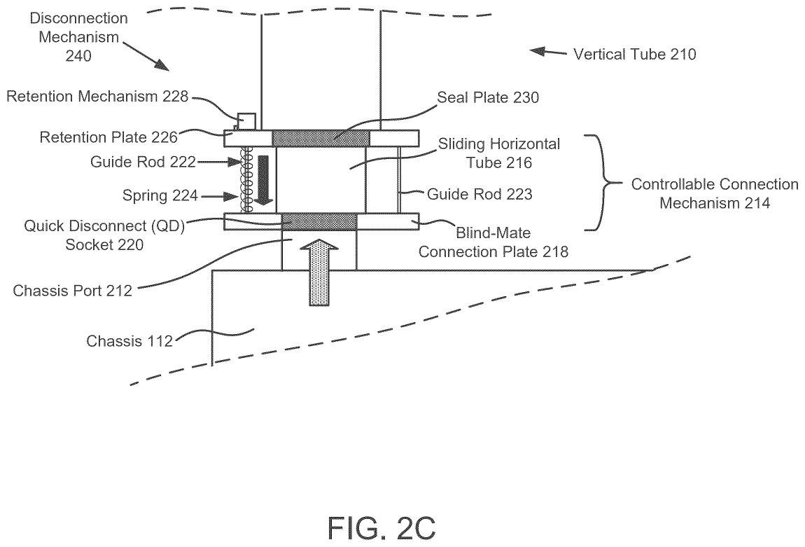

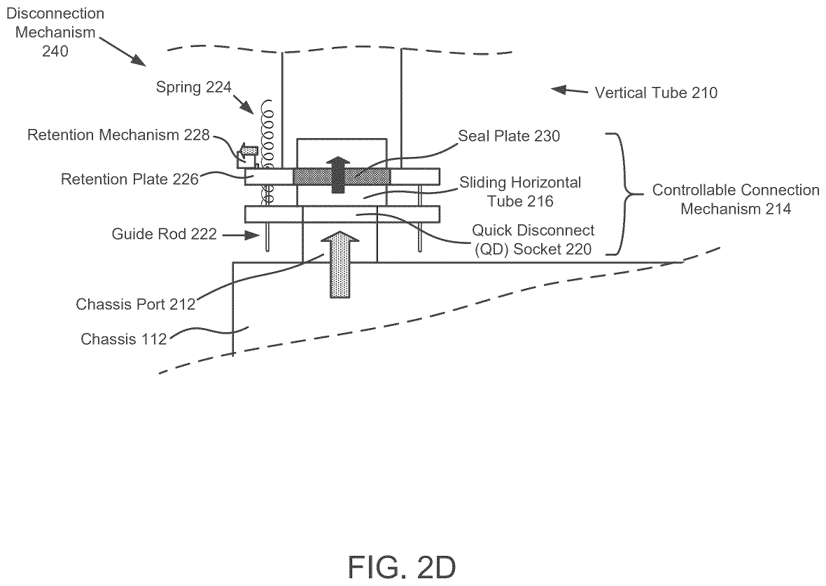

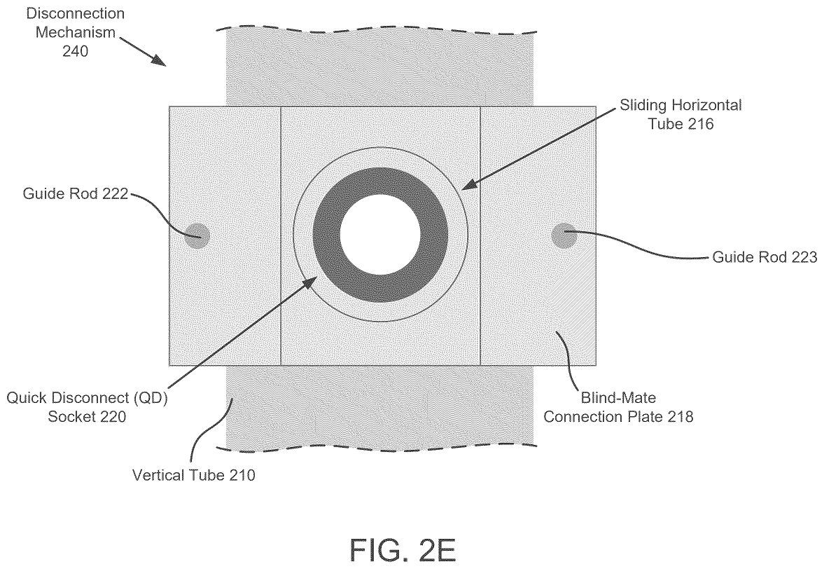

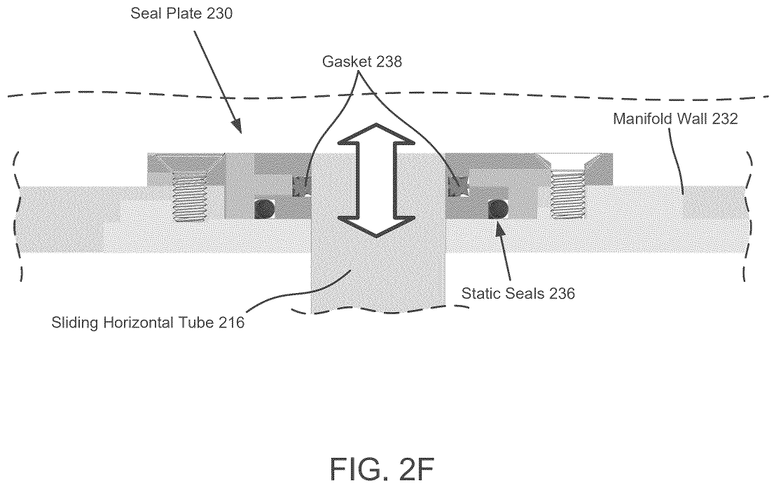

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of processing system 100, and/or any other type of devices positioned with a rack mount chassis system in which data processing system 100 may be placed (e.g., as shown in FIG. 2A).

Other types of computer implemented services may be provided by the system shown in FIG. 1 without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services.

For example, to facilitate the various functionalities, a hardware component may transmit data with other devices via various avenues of communication. For example, such avenues of communication may depend on physical operable connections that directly connect multiple hardware components to one another. To provide the above noted functionality, the system of FIG. 1 may include data processing system 100.

Data processing system 100 may include electronics 102, chassis 112, power components 104, and thermal components 106. Each of these is discussed below.

Electronics 102 may include at least a portion of the any number of hardware components, and as noted above, may provide computer implemented services. Hardware components of electronics 102 may be positioned on circuit cards and may generate heat while operating. Circuit cards may be pieces of circuit boards.

Electronics 102 and/or any other components of the any number of hardware components of data processing system 100 may be positioned in chassis 112. Chassis 112 may include an enclosure in which physical structures of electronics 102 (e.g., processors, memory, etc.), and/or other components of data processing system 100 may be positioned. For example, chassis 112 may facilitate placement and management of electronics 102 and/or other components (e.g., power components 104 and/or thermal components 106) in a computing environment such as those discussed below.

Power components 104 may power the any number of hardware components of data processing system 100. For example, power components 104 may be implemented using power supplies. Furthermore, operation of these power supplies may also contribute to the generation of heat. If left unregulated, this generation of heat may increase the likelihood of damage, as previously mentioned.

To manage the heat, data processing system 100 may include a liquid cooling system that is at least partially housed by chassis 112. This liquid cooling system may use (e.g., may include) a number of cooling components such as thermal components 106, and/or any other cooling components not shown in the system of FIG. 1.

It will be appreciated that for additional discussion of at least a portion of the any other cooling components not shown in the system of FIG. 1, refer to FIGS. 2A-2B.

Thermal components 106 may thermally manage any of the components of data processing system 100. For example, thermal components 106 may include thermal components such as cooling fans, coolant reservoirs, chillers, coolant (e.g., a cooling fluid), circulation pumps, and/or other components to facilitate performance of liquid-based cooling of at least some of electronics 102. For example, thermal components 106 may be used with cooling tubes 108 and liquid cooling block 110, each of which is discussed below.

Liquid cooling block 110 may facilitate a dissipation of heat generated by, for example, electronics 102 by circulating the cooling fluid through cooling tubes 108. To provide its functionality, liquid cooling block 110 may be, for example, a circulation pump. While providing its functionality, a transference of at least a portion of the generated heat may be facilitated.

For example, the cooling fluid, confined to a flow path that circulates through a loop of a liquid cooling system (e.g., cooling tubes 108 being at least a portion of the loop), may be placed in thermal communication with a hardware component generating the heat when the cooling fluid is flowing through a portion of the loop that is proximate to the hardware component. By being in this thermal communication, the cooling fluid may be heated while the heat generated by the hardware component is regulated.

Due to liquid cooling block 110 circulating the cooling fluid, this heated cooling fluid may flow to another portion of the loop. For example, components such as cooling fans may attempt to cool this another portion of the loop, thereby dissipating the heat of the cooling fluid as the cooling fluid flows through this another portion of the loop. Thus, the cooling fluid may be cyclically heated and cooled as the cooling fluid continues to flow through the loop, thereby contributing to the dissipation of heat generated by the any number of hardware components.

For example, the cooling liquid may be directed through an interior of liquid cooling block 110 and through a first portion of cooling tubes 108. Cooling tubes 108 may further facilitate the circulation by directing the cooling liquid, for example, to other portions of thermal components 106 adapted to cool the cooling liquid. To do so, cooling tubes 108 may include hollow, tubular structures in which liquid may flow through. For example, the cooling liquid, once cooled by the other portions, may then be further circulated through a second portion of cooling tubes 108 to direct the cooling liquid back through the liquid cooling block 110 to facilitate transference of additional heat generated by electronics 102.

However, by using the liquid cooling system discussed above, a likelihood of physically damaging the any number of hardware components (e.g., should a leak in liquid cooling block 110 and/or cooling tubes 108 occur) may be increased due to the presence of the cooling fluid. For example, if liquid cooling block 110 and/or cooling tubes 108 begin to leak, at least a portion of the cooling fluid may no longer be confined to the flow path that circulates through the loop of the liquid cooling system.

Consequently, should the any number of hardware components become exposed to liquid (e.g., the cooling fluid), functionality of the any number of hardware components may be negatively impacted, thereby negatively impacting the computer implemented services, previously discussed.

To mitigate this exposure, thereby decreasing the likelihood of damaging the hardware components, a controllable connection mechanism may be used with a fluid distribution system. This controllable connection mechanism may facilitate quick connections used in, for example, blind-mate connections between a chassis and, for example, a manifold through which cooling fluid flows and is provided to the liquid cooling system. Furthermore, this controllable connection mechanism may facilitate disconnections of (and maintain inaccessibility to) the quick connections based on any identified leaks in the system. Therefore, to provide its functionality, the controllable connection mechanism may include a quick connection and a disconnection mechanism. For additional information regarding the fluid distribution system and/or the quick connections of the controllable connection mechanism, refer to FIGS. 2A-2B.

Thus, any cooling fluid that may have circulated through the liquid cooling system just to escape into the interior of the chassis via the leak may instead be prevented from circulating, thereby preventing additional leaked cooling fluid from increasing the likelihood of negatively impacting the hardware components, their functionalities, and the computer implemented services that depend on these functionalities.

For additional information regarding the controllable connection mechanism, continue to the description of FIG. 2A, further below.

While illustrated in FIG. 1 with a limited number of specific components, a data processing system may include additional, fewer, and/or different components without departing from embodiments disclosed herein.

To further clarify embodiments disclosed herein, diagrams illustrating examples of data processing systems (and portions thereof) in accordance with embodiments are shown in FIGS. 2A-2F.

Turning to FIG. 2A, a diagram illustrating a side view of a rack system (e.g., 200) in accordance with an embodiment is shown (e.g., a front side and rear side of rack system 200 being depicted on a left-hand side and on a right-hand side, respectively, of the page).

Rack system 200 may be used to position and/or otherwise manage various chassis with regard to one another. To do so, rack system 200 may include rails 202 to fixedly secure each chassis to a respective height between the rails. For example, a second chassis may be positioned just under data processing system 100, separated by a distance along the length of rails 202.

Rack system 200 may include any number of mounted data processing systems. As shown in FIG. 2A, for example, data processing system 100 that is discussed with regard to FIG. 1 (e.g., illustrated with chassis 112 and liquid cooling block 110), the second data processing system (e.g., illustrated with chassis 204) positioned below data processing system 100, and/or any other data processing system not shown in FIG. 2A may be mounted on rack system 200.

As previously discussed, hardware components of data processing system 100 may generate heat during their operation. Such generation of heat may also occur in any other chassis mounted on rack system 200. This heat may be regulated (e.g., dissipated) by any number of liquid cooling systems (e.g., the liquid cooling system of data processing system 100, shown in FIG. 1).

Cooling fluid (e.g., as discussed with regard to FIG. 1) circulated through loops of the any number of liquid cooling systems may be provided by a fluid distribution system. This fluid distribution system may include a manifold positioned with rack system 200. For example, a manifold, depicted using vertical tubes 208 in FIG. 2A, may provide liquid cooling system loops of various mounted (to rack system 200) chassis (e.g., chassis 112 and 204) with cooling fluid. This manifold may also allow for cooling fluid to leave the chassis.

To provide the chassis with the cooling fluid, fluid communication may be established between each of the mounted chassis and vertical tubes 208. To establish this fluid communication, the system of FIG. 2A may include quick connections 206, discussed below with regard to FIG. 2B.

Turning to FIG. 2B, a diagram illustrating an expanded view of a portion of the manifold discussed with regard to FIG. 2A in accordance with an embodiment is shown.

As previously discussed, the manifold (e.g., vertical tubes 208) may provide cooling fluid to various chassis and/or may allow cooling fluid to leave these chassis. As shown in FIG. 2B, for example, the providing and receiving of cooling fluid is depicted using white arrows.

For example, assume the two shaded-in objects (shaded using different in-fill patterns) represent portions of cooling tubes 108 that lead away from chassis 112 and toward the manifold. The white arrows that overlap cooling tubes 108 may indicate a general direction in which cooling fluid flows within the tubular structures of cooling tubes 108.

For example, the darker shaded object of cooling tubes 108 may represent cooling fluid that has not been heated. Therefore, a general directional flow of the cooling fluid that flows through the darker shaded object is depicted with left-pointing arrows to indicate that the cooling fluid is being provided to chassis 112. The lighter shaded object of cooling tubes 108 may represent heated cooling fluid. Therefore, a general directional flow of the cooling fluid that flows through the lighter shaded object is depicted with right-pointing arrows to indicate that the cooling fluid is being received by the manifold.

As previously mentioned, to establish fluid communication between chassis 112 and the manifold, quick connections 206 may be used. Quick connections 206 may allow for a chassis such as chassis 112 to be positioned with rack system 200 such that a chassis port (not explicitly shown in FIG. 2B) of chassis 112 is secured (e.g., sealed) to a port of the manifold.

For example, a quick connection of quick connections 206 may be implemented using a compression tube connection type, and thus, may also be referred to as a quick-disconnect (QD) socket. This compression tube connection type may be implemented by pushing the chassis port and the port of the manifold against one another. By doing so, pressure may be applied to the QD socket. Once a pressure threshold is exceeded by this applied pressure, the connection may be successfully made, and the fluid communication may be established.

For example, due to the stationary position of the manifold with respect to rack system 200 (e.g., at the rear of the rack system), chassis 112 may be aligned with a rack of the rack system and pushed toward the rear of the rack system such that a chassis port positioned on a rear of chassis 112 is moved toward an aligned port of the manifold as chassis 112 is pushed. Chassis 112 may continue to be pushed until an amount of additional force (e.g., to exceed the pressure threshold) is required for secured attachment between the two ports to be facilitated, thereby sealing the QD socket.

Generally, disconnection of a QD socket may be manually facilitated. For example, connection and/or disconnection of a QD socket may be facilitated by a technician. However, assume a scenario in which the technician is not on site (e.g., is a significant distance away from the rack system such that the technician may not be able to prevent the hardware components from being negatively impacted by a leak).

Therefore, in this scenario, if a leak occurs and the technician is not available to sever the fluid communication, the manifold may continue to provide the cooling fluid to a chassis that houses the leak. Consequently, liquid may continue to enter an interior of the chassis, thereby increasing a likelihood of compromising (and/or otherwise negatively impacting) functionality of the hardware components.

To decrease the likelihood if negatively impacting the functionality of the hardware components (e.g., should a leak occur), a controllable connection mechanism (e.g., 214, discussed below with regard to FIG. 2C) may be used to allow for the fluid communication to be severed without facilitation by, for example, the technician.

To do so, the controllable connection mechanism may include a quick connection, such as the one discussed above, a disconnection mechanism, and a seal plate.

For additional information regarding the controllable connection mechanism, refer to FIGS. 2C-2F, below.

In FIGS. 2C-2F, diagrams of controllable connection mechanism 214 are shown in accordance with an embodiment. These diagrams may be used to discuss an example implementation of the controllable connection mechanism while depicting the controllable mechanism from multiple viewpoints.

Turning to FIG. 2C, a first diagram illustrating a controllable connection mechanism (e.g., 214) in accordance with an embodiment is shown. The viewpoint of FIG. 2C may be a top-down view of chassis 112, a front side of chassis 112 facing the bottom of the page while a rear side of chassis 112 faces a top of the page.

As previously mentioned with regard to FIG. 2B, to decrease the likelihood of negatively impacting the functionality of the hardware components (e.g., should a leak occur), controllable connection mechanism 214 may be used to facilitate and/or prevent/sever fluid communication between a port of chassis 112 (e.g., chassis port 212) and the manifold (shown in FIG. 2C with vertical tube 210, vertical tube 210 being one of vertical tubes 208 shown in FIGS. 2A-2B).

To do so, controllable connection mechanism 214 may include blind-mate connection plate 218, quick disconnect (QD) socket 220, retention plate 226, seal plate 230, and disconnection mechanism 240. Each of these is discussed below.

Blind-mate connection plate 218 may, in part, provide stability for controllable connection mechanism 214 while (i) chassis port 212 is connecting to the manifold, (ii) chassis port 212 is disconnecting from the manifold, and/or (iii) chassis port 212 is being prevented from connecting to the manifold. To provide its functionality, blind-mate connection plate 218 may be implemented using a structure positioned with QD socket 220 that has a flat, even surface facing chassis 112. This flat, even surface may have a width that spans a distance greater than the width of vertical tube 210. A portion of the flat, even surface that extends past the width of vertical tube 210 may include a hole that spans through the entire depth of the structure (e.g., from front to back) and through which at least a portion of a guide rod (e.g., 222), discussed further below, may extend through. Thus, the hole may provide a through-point for guide rod 222 while, for example, blind-mate connection plate 218 is pushed along an axis perpendicular to vertical tube 210 when chassis port 212 pushes against QD socket 220.

QD socket 220 may place chassis 112 in fluid communication with the manifold based on pressure applied against QD socket 220 by chassis port 212, the pressure needing to exceed a pressure threshold for QD socket 220 to allow the connection. To provide its functionality, QD socket 220 may be implemented with a compression tube connection type (a quick connection), discussed previously with regard to quick connections 206 in FIG. 2B.

Additionally, QD socket 220 may be positioned with blind-mate connection plate 218 as mentioned above. By being positioned with blind-mate connection plate 218, QD socket 220 may be limited to a range of motion along the axis perpendicular to vertical tube 210 when being physically pushed by chassis port 212. This limited range of motion may maintain an alignment of controllable connection mechanism 214 such that chassis port 212 remains aligned with QD socket 220, and QD socket 220 remains aligned with a port of the manifold through which the cooling fluid may flow.

Retention Plate 226 may almost entirely prevent the limited range motion based on a retention mechanism (e.g., 228) of disconnection mechanism 240 (discussed further below), the retention mechanism being positioned with a special through-point of retention plate 226. This special through-point may be adapted to allow passage of at least a portion of a spring (e.g., 224) of disconnection mechanism 240 through the depth of retention mechanism 226.

To provide its functionality, retention plate 226 may be implemented using another structure that has a flat, even surface with another width that spans another distance past the width of vertical tube 210, similar to blind-mate connection plate 218. The hole through blind-mate connection plate 218 may align with the special through-point, allowing guide rod 222 to extend out from the special through-point and toward chassis 112, at least a portion of guide rod 222 extending into the hole of blind-mate connection plate 218.

Seal plate 230 may prevent leaks between a sliding horizontal tube of disconnection mechanism 240 and vertical tube 210 while allowing the sliding horizontal tube to move along the axis perpendicular to vertical tube 210 when blind-mate connection plate 218 is pushed a distance along the axis by chassis port 212.

To provide its functionality, seal plate 230 may be implemented using (i) a first sealing surface to seal the seal plate to vertical tube 210, and (ii) a second sealing surface to seal the seal plate to the sliding horizontal tube.

For additional information regarding seal plate 230, refer to FIG. 2F.

Disconnection mechanism 240 may, based on an identification of a leak within chassis 112, (i) sever the fluid communication after the fluid communication is established by QD socket 220, and (ii) prevent the fluid communication from being reestablished until the leak is repaired. To provide its functionality, disconnection mechanism 240 may include sliding horizontal tube 216, retention mechanism 228, guide rod 222, and spring 224. Each of these is discussed below.

Sliding horizontal tube 216 may be adapted to (i) allow fluid to flow from vertical tube 210 while fluid communication is established by, for example, QD socket 220, and (ii) slide a distance into at least a portion of a body of the manifold (e.g., partially slide into vertical tube 210), the distance slid being along an axis that is perpendicular to vertical tube 210.

To provide its functionality, sliding horizontal tube 216 may be implemented using a hollow tubular structure positioned with blind-mate connection mechanism 218 such that these two components may move in unison. For example, pushing blind-mate connection mechanism 218 a centimeter towards retention plate 226 caused sliding horizontal tube 216 to slide into the body of the manifold by a millimeter, both moving simultaneously to one another and in a same direction (e.g., along the perpendicular axis).

Retention mechanism 228 may, in part, (i) almost entirely prevent movement along the perpendicular axis by preventing passage of spring 224 through the special through-point of retention plate 226, and/or (ii) based on an identification of a leak within chassis 112, allow the movement along the perpendicular axis by allowing spring 224 to pass through the special through-point at least partially.

To provide its functionality, retention mechanism 228 may be implemented by, for example, a mechanical structure that when actuated by a motor may rotate to either cover the special through-point or uncover the special through-point. This actuation may be based on a signal received by a controller of, for example, data processing system 100. For example, while covering the through-point, the controller may receive data from sensors placed within an interior of chassis 122 identifying a leak in a cooling system at least partially housed by chassis 112. Based on this identification, the controller may transmit a signal, thereby providing a command for the motor to rotate the mechanical structure, thereby uncovering the special through-point and leaving passage through the special through-point uncontested.

Guide rod 222 may maintain alignment of portions of controllable connection mechanism 214. To provide its functionality, guide rod 222 may be implemented using, for example, metal rods. These metal rods may have a size adapted to (i) be positioned with the special through-point such that the metal rod extends toward a hole of blind-mate connection plate 218, (ii) be inserted through a hole of blind-mate connection plate 218, and (iii) allow for blind-mate connection plate 218 to move along the previously mentioned perpendicular axis when the special through-point is not covered by retention mechanism 226 and blind-mate connection plate 218 is pushed by chassis port 212.

It will be appreciated that although described using a single guide rod (e.g., 222), a controllable connection mechanism may include any number of guide rods (e.g., guide rod 222 and guide rod 223, as depicted in FIGS. 2C-2E) spanning distances between holes of the two plates (retention plate 226 and blind-mate connection plate 218).

Spring 224 may apply pressure on both retention plate 226 and blind-mate connection plate 218 while the special through-point is covered by retention mechanism 228. By applying this pressure, both of the two plates may be prevented from nearing one another (e.g., when blind-mate connection plate 218 moves along the perpendicular axis, towards retention plate 226) when blind-mate connection plate is pushed by chassis port 212. However, when the special through-point is uncovered, tension responsible for compressing spring 224 between the two plates may be released as spring 224 is at least partially expanded through the special through-point.

By providing the above functionalities, controllable connection mechanism 214 may both facilitate connections allowing fluid communication between a fluid distribution system and liquid cooling systems and sever and/or prevent the connections based on identification of leaks within the liquid cooling systems. In doing so, data processing systems may be protected from damage caused by leaks automatically upon identification of the leaks.

For example, assume a technician prepares a rack system (e.g., 200) for a client desiring liquid cooling systems to be housed in each chassis (such as chassis 112 and chassis 204 in FIG. 2A) mounted on racks of the rack system. Due to the technician knowing that he/she will be a significant distance from the rack system for quite some time after this initial setup, the technician checks that there are no present leaks in the liquid cooling systems and utilizes a controllable connection mechanism (e.g., 214) to connect a fluid distribution system positioned at a rear of the rack system with each chassis.

As shown in FIG. 2C, the technician may place chassis 112 on one of the racks, thereby aligning chassis port 212 with QD socket 220, and push chassis 112 toward the rear of the rack system, causing chassis port 212 to make physical contact with QD socket 220. Additionally, due to there being no leaks in the liquid cooling systems, retention mechanism 228 may be initially set (e.g., by the technician) to cover a hole (e.g., the special through-point) in retention plate 226 that is positioned with spring 224. Because the hole is covered, spring 224 may be compressed between retention plate 226 and blind-mate connection plate 218, thereby maintaining a consistent distance between these two plates while the controllable connection mechanism is undisturbed (e.g., only being disturbed by continued pushing by the technician).

However, to successfully make the connection to establish fluid communication between the fluid distribution system and a liquid cooling system housed by chassis 112, a force exceeding a pressure threshold must be applied to QD socket 220. Therefore, the technician may continue to push chassis 112, thus causing chassis port 212 to apply an amount of pressure onto QD socket 220 (depicted by the large, shaded arrow pointing towards the top of the page in FIG. 2C). Based on QD socket 220 being positioned with blind-mate connection plate 218, blind-mate connection plate 218 may attempt to move along an axis towards retention plate 226 while the amount of pressure is applied by chassis port 212.

By attempting to move along the axis, blind-mate connection plate 218 may cause the tension compressing spring 224 to increase. Consequently, spring 224 may push back on blind-mate connection plate 218 (depicted by the smaller black arrow pointing towards a bottom of the page in FIG. 2C). In doing so, the pressure between chassis port 212 and QD socket 220 may easily exceed the pressure threshold, thereby forcing chassis port 212 entry into QD socket 220 and successfully facilitating the connection. Thus, the fluid communication may be established (depicted by QD socket 220 being shaded in).

After some time has passed (e.g., 3 months), a cooling tube of the liquid cooling system may be ever so slightly disconnected from a liquid cooling block (e.g., 110), the cooling tube having been pulling away from the liquid cooling block since being prepared by the technician, and thus, the slight disconnection being inevitable. Based on this slight disconnection, a leak becomes present in chassis 112, discussed further below with regard to FIG. 2D.

Turning to FIG. 2D, a second diagram illustrating a controllable connection mechanism (e.g., 214) in accordance with an embodiment is shown. The viewpoint of FIG. 2D may be a top-down view of chassis 112, similar to that of FIG. 2C.

As mentioned above, a leak may become present in chassis 112. A leak sensor positioned in the interior of chassis 112 may detect the leak, the leak sensor being adapted to detect leaks due to the cooling fluid. This leak sensor may be operably connected to controllable connection mechanism 214, and/or a controller that manages the disconnection mechanism of controllable connection mechanism 214, to activate retention mechanism 228 when a leak is present. Thus, retention mechanism 228 may be activated.

As shown in FIG. 2D, retention mechanism 228 may be activated (depicted by a small, shaded arrow pointing towards a left of the page), thereby uncovering the hole that, in part, was compressing spring 224. The tension stored in spring 224 may cause at least a portion of spring 224 to extend through the hole, allowing spring 224 to decompress.

Consequently, the lack of tension may allow blind-mate connection plate 218 (that has, until now, applied a constant pressure against spring 224 while trying to move along the axis) to begin moving towards retention plate 226 (depicted by a large, shaded arrow pointing towards a top of the page) while guided by guide rods 222-223 along the axis.

Based on this movement (and reversal of force, the movement pulling QD socket 220 away from chassis port 212 rather than towards) by blind-mate connection plate 218, the amount of pressure being applied to QD socket 220 may decrease significantly, causing the amount of pressure to fall below the pressure threshold.

Once the amount of pressure is below the pressure threshold, QD socket 220 may disconnect from chassis port 212 (depicted by the shaded illustration of QD socket 220 in FIG. 2C being instead depicted as unshaded in FIG. 2D), QD socket 220 moving with blind-mate connection plate 218 along the axis and away from chassis port 212.

The integral components of controllable mechanism 214 that allow this movement of QD socket 220 may be, at least in part, (i) sliding horizontal tube 216 and (ii) seal plate 230. For example, because blind-mate connection plate 218 is positioned with (e.g., attached to) sliding horizontal tube 216, this movement may move QD socket 220, as well as sliding horizontal tube 216, along the axis (depicted by a small, black arrow pointing towards a top of the page in FIG. 2D).

However, the fluid distribution system may be immobile and unable to provide any give to objects applying pressure to a manifold wall of the fluid distribution system. Fortunately, seal plate 230 may be adapted to (i) seal the physical connection between the manifold and sliding horizontal tube 216, and to (ii) allow sliding horizontal tube 216 to move with blind-mate connection plate 218. To do so, seal plate 230 may facilitate a breach of the manifold through which sliding horizontal tube 216 may slide through the manifold wall, and at least partially into an interior of a tube (e.g., 210) of the manifold.

For additional information regarding seal plate 230 refer to FIG. 2F.

The tube (e.g., 210) may be a portion of the manifold through which cooling fluid flows and that may be provided (e.g., when the fluid communication is facilitated) to the liquid cooling system housed in chassis 112.

For example, this tube may be that which is described as connecting to a portion of cooling tubes 108 depicted using the darker in-fill pattern discussed in FIG. 2B (e.g., also depicted by vertical tube 210 in FIGS. 2C and 2D without an in-fill pattern). For example, this portion that is depicted using the darker in-fill pattern may be where the cooling fluid has initially entered the liquid cooling system. Therefore, by disconnecting chassis port 212 from the manifold based on the identification of the leak, a flow of the cooling fluid into the chassis may be halted. Thus, the fluid communication may be severed, thereby decreasing a likelihood of negatively impacting functionality of hardware components housed in chassis 112 that may have otherwise been caused by continuously leaking cooling fluid.

However, assume an additional scenario in which a user of chassis 112 (e.g., the client) is on-site with the rack system and becomes aware of, for example, a lack of cooling (e.g., overheating) of chassis 112 and/or a shutdown of components housed by chassis 112 initiated by an error to which the user is made aware (e.g., the user is notified by various other system and/or by other means). The user, believing that maybe chassis 112 had been repositioned by a clumsy intern, attempts to push chassis 112 toward a rear of the rack system. Consequently, and as shown in FIG. 2D, chassis port 212 may physically push blind-mate connection plate 218 along the axis while maintaining the disconnection between chassis port 212 and QD socket 220.

For additional information regarding and/or an additional viewpoint depicting disconnection mechanism 240, refer to FIG. 2E further below.

Frustrated, the user may request repair from the technician, the technician being free of worry that the leak is progressively damaging any of the rack system beyond what damage occurred during the initial occurrence of the leak. The technician may then be able to promptly but calmy travel to the rack system's location. Once on-site, the technician may be able to repair the leak, provide additional servicing to the rack system, and reset controllable connection mechanism 214 to continue providing a means for mitigating damage caused by leaks that occur in the rack system. For example, the technician may reset the mechanism by repositioning spring 224 and the retention mechanism 228 such that the fluid communication may be reestablished once chassis 112 is pushed into the rack system.

Turning to FIG. 2E, a third diagram illustrating a controllable connection mechanism (e.g., 214) in accordance with an embodiment is shown.

The viewpoint of FIG. 2E may be a front view of the controllable connection mechanism (and therefore, a front view of disconnection mechanism 240). For example, a front of controllable connection mechanism 214 (that faces a same direction as the front side of chassis 112, as depicted in FIGS. 2C-2D) may face out of the page while a rear of controllable connection mechanism 214 faces into the page.

It will be appreciated that the viewpoint shown in FIG. 2E may be a same view as that faced by a receiving end of chassis port 212 while chassis 112 is pushed toward the rear of the rack system.

The flat, even structure of blind-mate connection plate 218 positioned with QD socket 220 and sliding horizontal tube 216, as shown in FIG. 2E, may prevent pressure from being disproportionately applied across a surface of blind-mate connection plate 218 (e.g., may prevent disproportionate force from being applied by chassis port 212 when pushed by, for example, either the technician and/or the user). In doing so, a smooth movement of blind-mate connection plate 218 (and therefore, simultaneous smooth movement of respective components positioned with blind-mate connection plate 218) may be guided by guide rods 222 and 223 along the axis (e.g., into the page).

Turning to FIG. 2F, a fourth diagram illustrating a controllable connection mechanism (e.g., 214) in accordance with an embodiment is shown. The viewpoint of FIG. 2F may be an expanded top-down view of controllable connection mechanism 214 that is similar to that of FIGS. 2C-2D but expanded to depict components of seal plate 230.

As previously discussed, seal plate 230 may be adapted to (i) seal the physical connection between the manifold (e.g., vertical tube 210) and sliding horizontal tube 216, and to (ii) allow sliding horizontal tube 216 to move with blind-mate connection plate 218.

To do so, previously mentioned with regard to FIG. 2C, seal plate 230 may be implemented using (i) a first sealing surface to seal the seal plate to, for example, manifold wall 232, and (ii) a second sealing surface to seal the seal plate to the sliding horizontal tube. Each of these surfaces is discussed below.

To provide its functionality, the first sealing surface may include static seals 236. Static seals 236 may be implemented by sealing structures wedged between the first sealing surface and manifold wall 232. Such placement of static seals 236 may fixedly secure seal plate 230 to the manifold such that the first sealing surface remains undisturbed while sliding horizontal tube 216 provides its own functionality involving movement along the previously mentioned perpendicular axis (e.g., to enter into at least a portion of an interior of vertical tube 210, housed by manifold wall 232).

To provide its functionality, the second sealing surface may include gasket 238 positioned between the second sealing surface and sliding horizontal tube 216. Gasket 238 may be implemented by, for example, a gasket adapted to prevent cooling fluid escaping from an interior of vertical tube 210 and/or sliding horizontal tube 216. For example, as the cooling fluid flows through vertical tube 210, into sliding horizontal tube 216, and (while in fluid communication) through chassis port 212 (shown in FIGS. 2C-2D), gasket 238 may be adapted to prevent leakage while also not preventing the movement of sliding horizontal tube 216 along the perpendicular axis. For example, if a structure such as static seal 236 were to replace gasket 238, the movement along the perpendicular axis would be prevented.

Thus, as discussed with regard to FIGS. 2C-2F, the controllable connection mechanism may prevent damage caused by any leaks in a liquid cooling system by severing fluid communication, and preventing the fluid communication from reestablishing, based on identification of the leaks in a system. In doing so, the likelihood of negatively impacting hardware components due to the leaked liquid may be decreased. Therefore, the likelihood of negatively impacting the computer implemented services may also be decreased.

While illustrated in FIGS. 2A-2F with a limited number of specific components, a system may include additional, fewer, and/or different components without departing from embodiments disclosed herein.

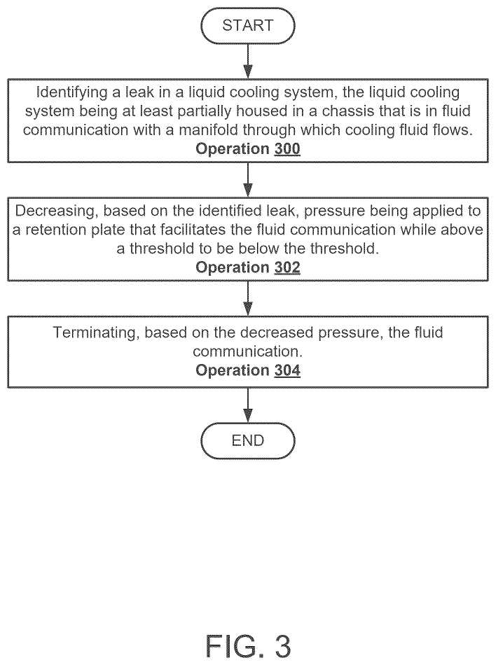

As discussed above, the components of FIGS. 2A-2F may facilitate and/or perform various functionalities to manage data processing systems. FIG. 3 illustrates methods that may be facilitated and/or performed by the components of FIG. 2A-2F.

In the diagram discussed below and shown in FIG. 3, any of the operations may be repeated, performed in different orders, and/or performed in parallel with or in a partially overlapping in time manner with other operations.

Turning to FIG. 3, a flow diagram illustrating a method for managing operation of a data processing system by, for example, mitigating negative impacts caused by liquid that escaped from a liquid cooling system, in accordance with an embodiment is shown. The method may be facilitated and/or performed, at least in part, for example, by a controllable connection mechanism of a rack system (e.g., 200) and/or any other entity.

At operation 300, a leak in a liquid cooling system is identified, the liquid cooling system being at least partially housed in a chassis that is in fluid communication with a manifold through which cooling fluid flows. The leak may be identified by, for example, sensing functionality of a leak sensor positioned in the interior of the chassis, adapted to detect leaks due to cooling fluid, and operably connected to a disconnection mechanism to activate the disconnection mechanism when a leak is present.

This sensing functionality may be provided by (i) obtaining information indicating the leak (e.g., obtaining distinctive patterns of sound that escaping fluid is known to produce, obtaining pressure changes within a loop of the liquid cooling system through which cooling fluid flows, proximate traversal of the cooling fluid passed the leak sensor, etc.), and (ii) providing this information to, for example, a processor (e.g., and/or otherwise controller of the disconnection mechanism) of the data processing system via a data transmission that includes the information.

For example, cooling fluid may flow through an interior of the chassis to cool a hardware component that contributes to computer implemented services of the data processing system, the flow being facilitated by the liquid cooling system. A breach in the structure (e.g., a normally enclosed loop, if not for the breach) of the liquid cooling system may allow the flow to at least partially diverge outside an interior of the normally enclosed loop. This divergence may allow possible direct contact with the hardware component and/or operable connections of the hardware component.

By detecting, for example, the distinctive patterns of sound, the leak sensor may transmit data indicating detection of such sound to the processor.

At operation 302, based on the identified leak, pressure being applied to a retention plate that facilitates the fluid communication while above a threshold is decreased to be below the threshold. This pressure may be decreased by (i) obtaining, by a retention mechanism of the disconnection mechanism, a signal for actuation of the retention mechanism (e.g., by a motor), and (ii) actuating, based on the signal, the retention mechanism.

This signal, for example, may be obtained via a data transmission provided by the processor, the data transmission including a command for the motor to actuate the retention mechanism, thereby moving the retention mechanism from a first position to a second position. This actuation may reposition the retention mechanism such that a spring of the disconnection mechanism may be allowed to expand passed the first position that was previously blocked by the retention mechanism.

For example, prior to the actuation, the spring may be compressed between the retention plate and a blind-mate connection plate that is positioned with a quick disconnect (QD) socket. Furthermore, this QD socket may depend on the applied pressure being above the pressure threshold to push against a port of the chassis, thereby continuing fluid communication with the chassis. If not for the compression of the spring between these plates, the blind-mate connection plate, along with the QD socket, may not be prevented from moving toward the retention plate and away from the chassis.

By actuating the retention mechanism, the spring may decompress by expanding passed the first position, and therefore, passed the retention plate. In doing so, tension caused by the compression, which is at least in part responsible for the pressure applied to the retention plate, may be released by the actuation.

By releasing this tension and allowing decompression of the spring, the pressure being applied to the retention plate may be decreased, thereby allowing the blind-mate connection plate to move toward the retention plate. In doing so, the QD socket may stop pushing against the port of the chassis, and the pressure threshold may no longer be exceeded.

At operation 304, based on the decreased pressure, the fluid communication is terminated. The fluid communication may be terminated by movement of the blind-mate connection plate, and therefore, movement of the QD socket, away from the chassis. In doing so, the QD socket may disconnect from the port of the chassis, thus ending the fluid communication.

The method may end following operation 304.

Thus, using the method illustrated in FIG. 3, embodiments disclosed herein may manage data processing systems while mitigating risks associated with using a liquid to facilitate such management. To do so, a controllable connection mechanism may be used to control fluid communication between a fluid distribution system and, for example, data processing systems in a rack system.

In doing so, liquid escaping into an interior of a data processing system chassis may be limited. This limitation may prevent additional liquid from negatively impacting the functionality of hardware components housed in the chassis. Thus, a likelihood of negatively impacting hardware functionality may be decreased and may in turn decrease a likelihood of negatively impacting computer implemented services provided by the data processing systems.

The aforementioned method, and components described with respect to FIGS. 1-3, may be used with a data processing system to facilitate cooling of components of the data processing system while mitigating risk associated with using a liquid in the cooling process.

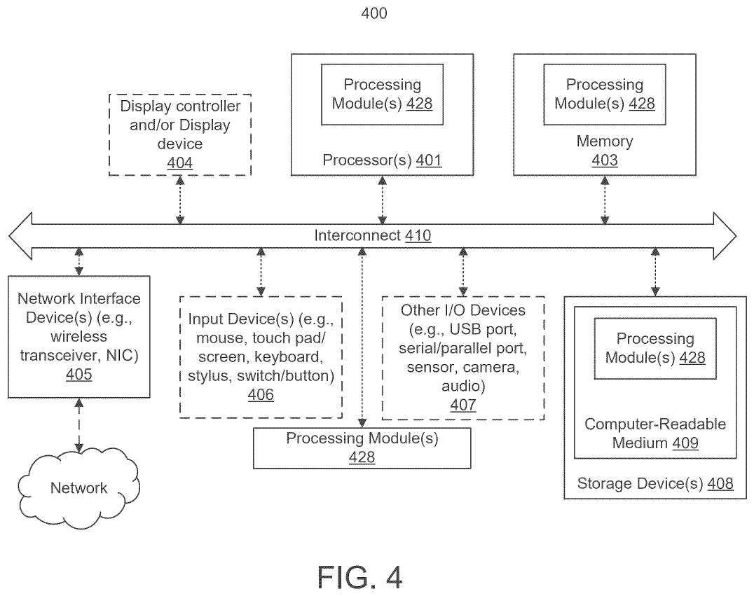

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A rack system, comprising:
a chassis adapted to house hardware components of a data processing system that provides computer implemented services;
a quick connection adapted to place the chassis in fluid communication with a manifold through which cooling fluid flows; and
a disconnection mechanism adapted to disconnect the quick connection while the chassis is positioned at a first location in a rack, the quick connection being inaccessible while the chassis is at the first location.

2. The rack system of claim 1, wherein the disconnection mechanism comprises:
a sliding horizontal tube that:
connects a vertical tube of the manifold with the quick connection; and
is adapted to slide into the vertical tube to facilitate repositioning of the quick connection.

3. The rack system of claim 2, further comprising:
A seal plate comprising:
A first sealing surface to seal the seal plate to the vertical tube and a second sealing surface to seal the seal plate to a slidable tube that connects the quick connection to the vertical tube.

4. The rack system of claim 1, wherein the disconnection mechanism comprises:
a spring adapted to apply force to a blind-mate connection plate on which the quick connection is positioned, the force preventing the quick connection from moving away from the chassis when the chassis applies force to the quick connection.

5. The rack system of claim 4, wherein the disconnection mechanism further comprises:
a retention mechanism adapted to effectively prevent the spring from applying the force to the blind-mate connection plate.

6. The rack system of claim 5, wherein the disconnection mechanism further comprises:
a guide rod that controls a movement path of the blind-mate connection plate when the retention mechanism prevents the spring from applying the force to the blind-mate connection plate.

7. The rack system of claim 6, wherein the movement path is aligned with a movement path of the chassis when the chassis is positioned at the first location.

8. The rack system of claim 7, wherein the movement path moves the quick connection away from the chassis.

9. The rack system of claim 1, wherein the cooling fluid flows through an interior of the chassis to cool a hardware component that contributes to the computer implemented services.

10. The rack system of claim 9, further comprising:
a leak sensor positioned in the interior of the chassis, adapted to detect leaks due to the cooling fluid, and operably connected to the disconnection mechanism to activate the disconnection mechanism when a leak is present.

11. A system comprising:
a quick connection adapted to place a chassis in fluid communication with a manifold through which cooling fluid flows; and
a disconnection mechanism adapted to disconnect the quick connection while the chassis is positioned at a first location in a rack, the quick connection being inaccessible while the chassis is at the first location.

12. The system of claim 11, wherein the disconnection mechanism comprises:
a sliding horizontal tube that:
connects a vertical tube of the manifold with the quick connection; and
is adapted to slide into the vertical tube to facilitate repositioning of the quick connection.

13. The system of claim 12, further comprising:
A seal plate comprising:
A first sealing surface to seal the seal plate to the vertical tube and a second sealing surface to seal the seal plate to a slidable tube that connects the quick connection to the vertical tube.

14. The system of claim 11, wherein the disconnection mechanism comprises:
a spring adapted to apply force to a blind-mate connection plate on which the quick connection is positioned, the force preventing the quick connection from moving away from the chassis when the chassis applies force to the quick connection.

15. The system of claim 14, wherein the disconnection mechanism further comprises:
a retention mechanism adapted to effectively prevent the spring from applying the force to the blind-mate connection plate.

16. The system of claim 15, wherein the disconnection mechanism further comprises:
a guide rod that controls a movement path of the blind-mate connection plate when the retention mechanism prevents the spring from applying the force to the blind-mate connection plate.

17. The system of claim 16, wherein the movement path is aligned with a movement path of the chassis when the chassis is positioned at the first location.

18. The system of claim 17, wherein the movement path moves the quick connection away from the chassis.

19. The system of claim 11, wherein the cooling fluid flows through an interior of the chassis to cool a hardware component that contributes to computer implemented services.

20. The system of claim 19, further comprising:
a leak sensor positioned in the interior of the chassis, adapted to detect leaks due to the cooling fluid, and operably connected to the disconnection mechanism to activate the disconnection mechanism when a leak is present.
